(19) United States
(12) Patent Application Publication
(10) Pub. No.: US 2025/0273174 A1
(43) Pub. Date: Aug. 28, 2025

(54) Display Apparatus

(71) Applicant: LG Display Co., Ltd., Seoul (KR)

(72) Inventors: Su-Bin PARK, Paju-si (KR); Jun HEO, Paju-si (KR); Kyung-Seok KIM, Paju-si (KR); Seung-Wook YOO, Paju-si (KR); Rak-Hee PARK, Paju-si (KR)

(21) Appl. No.: 19/001,917

(22) Filed: Dec. 26, 2024

(30) Foreign Application Priority Data
Feb. 27, 2024 (KR) 10-2024-0027786

(51) Int. Cl. G09G 3/3291; G09G 3/3225

(52) U.S. Cl. CPC G09G 3/3291; G09G 3/3225; G09G 2300/0819; G09G 2300/0842; G09G 2310/0286; G09G 2310/06; G09G 2310/08; G09G 2320/0233; G09G 2330/045; G09G 2360/14

(57) ABSTRACT

A display apparatus includes: a display panel including a plurality of data lines and a plurality of pixels; first and second data driving portions including a plurality of first and second data ICs; a timing control portion providing input first and second lock signals to the first and second data driving portions, respectively; and a comparison circuit receiving output first and second lock signals generated from the first and second data driving portions according to the input first and second lock signals, respectively, and comparing and synchronizing the output first and second lock signals to provide a synchronous lock signal to the timing control portion, wherein in a lock state of the synchronous lock signal, the timing control portion transmits image data to the first and second data driving portions, and the first and second data driving portions output respective data voltages.

### CROSS REFERENCE TO RELATED APPLICATION

The present application claims the priority benefit of Republic of Korea Patent Application No. 10-2024-0027786 filed on Feb. 27, 2024, which is hereby incorporated by reference in its entirety.

### BACKGROUND

The present disclosure relates to a display apparatus.

### TECHNICAL FIELD

As the information society develops, a demand for display apparatuses for displaying images have increased in various forms, and in recent years, various flat display apparatuses such as organic light emitting display apparatuses and liquid crystal display apparatuses have been used.

Recently, the organic light emitting display apparatus is driven by a double bank structure in which data driving portions are placed at both ends of a data line. In the double bank structure, the same lock signal is input to upper and lower data driving portions simultaneously, and in response to the lock signal, the upper and lower data driving portions each generate and output an output lock signal.

However, due to differences in electrical characteristics between the upper and lower data driving portions, the timings of the output lock signals may not match and may be asynchronous.

In this case, the output timings of the upper and lower data driving portions may not match and may be asynchronous, causing a potential difference in a data voltage between upper and lower channels, which may cause an overcurrent. This overcurrent may cause a data IC (Integrated Circuits) to heat up or burn.

### SUMMARY

An advantage of the present disclosure is to provide a display apparatus that can improve occurrence of overcurrent between upper and lower channels due to asynchronous output lock signals of upper and lower data driving portions of a double bank structure.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display apparatus includes: a display panel including a plurality of data lines and a plurality of pixels respectively connected to the plurality of data lines; a first data driving portion including a plurality of first data ICs connected to one ends of the plurality of data lines; a second data driving portion including a plurality of second data ICs connected to the other ends of the plurality of data lines; a timing control portion providing input first and second lock signals to the first and second data driving portions, respectively; and a comparison circuit receiving output first and second lock signals generated from the first and second data driving portions according to the input first and second lock signals, respectively, and comparing and synchronizing the output first and second lock signals to provide a synchronous lock signal to the timing control portion, wherein in a lock state of the synchronous lock signal, the timing control portion transmits image data to the first and second data driving portions, and the first and second data driving portions output respective data voltages.

In another embodiment, a display apparatus includes: a display panel including a plurality of data lines and a plurality of pixels respectively connected to the plurality of data lines; a first data driving portion including a plurality of first data ICs connected to one ends of the plurality of data lines; a second data driving portion including a plurality of second data ICs connected to the other ends of the plurality of data lines; a timing control portion providing input first and second lock signals to the first and second data driving portions, respectively; and a comparison circuit receiving output first and second lock signals generated from the first and second data driving portions according to the input first and second lock signals, respectively, and comparing and synchronizing the output first and second lock signals to provide a synchronous lock signal to the timing control portion, wherein outputs of data voltages of the first and second data driving portions are adjusted according to the synchronous lock signal.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a display apparatus according to an embodiment of the present disclosure;

FIG. 2 is a circuit view schematically illustrating an example of a pixel according to an embodiment of the present disclosure;

FIG. 3 is a view illustrating a configuration of a gate driving portion of a display apparatus according to an embodiment of the present disclosure;

FIG. 4 is a timing chart schematically illustrating an example of driving signals output from a gate driving portion according to an embodiment of the present disclosure;

FIG. 5 is a cross-sectional view schematically illustrating an example of a cross-sectional structure of a display panel according to an embodiment of the present disclosure;

FIG. 6 is a view schematically illustrating a timing control portion, a data driving portion, and a comparison circuit of a display apparatus according to an embodiment of the present disclosure;

FIG. 7 is a timing chart schematically illustrating input and output lock signals, a synchronous lock signal, and data voltages according to an embodiment of the present disclosure;

FIG. 8 is a timing chart schematically illustrating an example of input and output lock signals, a synchronous lock signal, and data voltages in a case of output lock signals having asynchronization and a lock failure according to an embodiment of the present disclosure; and

FIG. 9 is a timing chart schematically illustrating input and output lock signals and data voltages in a case of output lock signals having asynchronization and lock failure according to a comparative example.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure can be defined by the scope of the claims.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When ‘comprising’, ‘including’, and ‘having’, and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present disclosure, terms such as first, second and the like can be used. These terms are only for distinguishing the components from other components, and an essence, order, sequence, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, embodiments of the present disclosure are described in detail with reference to the drawings. Meanwhile, in the following embodiments, the same and like reference numerals are assigned to the same and like components, and detailed descriptions thereof can be omitted.

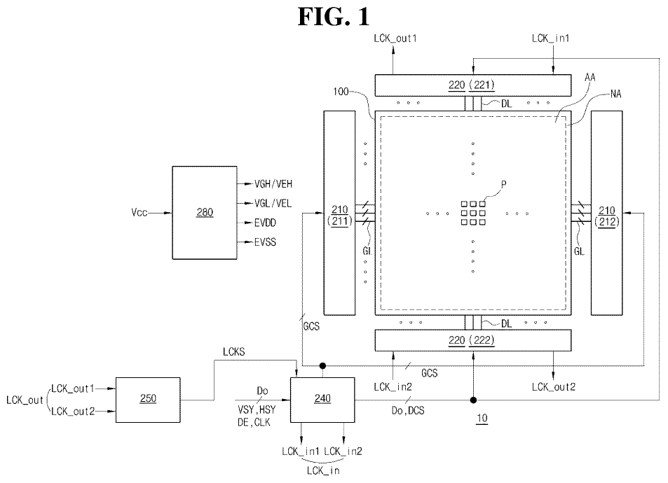

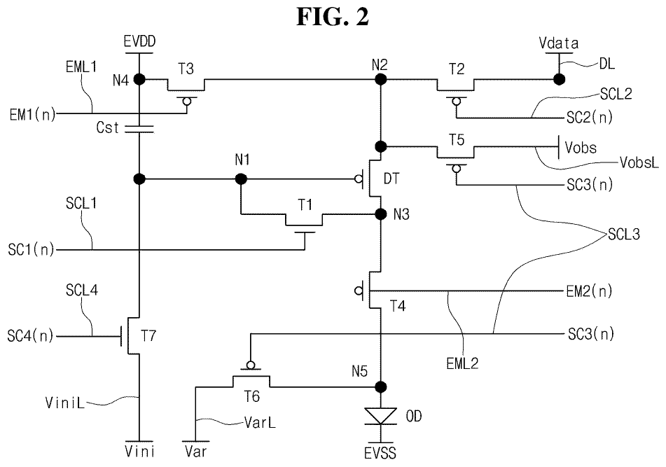

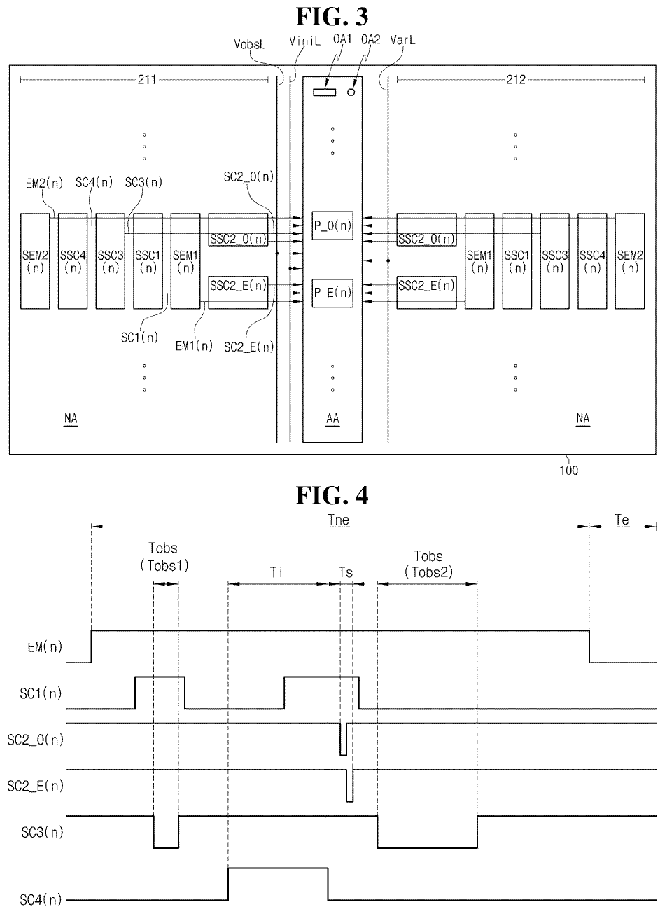

FIG. 1 is a view schematically illustrating a display apparatus according to an embodiment of the present disclosure. FIG. 2 is a circuit view schematically illustrating an example of a pixel according to an embodiment of the present disclosure. FIG. 3 is a view illustrating a configuration of a gate driving portion of a display apparatus according to an embodiment of the present disclosure. FIG. 4 is a timing chart schematically illustrating an example of driving signals output from a gate driving portion according to an embodiment of the present disclosure.

Prior to a specific description, the display apparatus 10 according to the present embodiment can include one of all types of display apparatuses, including a light emitting display apparatus with a light emitting diode, to which a data driving with a double bank structure is applied.

Meanwhile, for convenience of explanation, in this embodiment, an organic light emitting display apparatus is described as an example of the display apparatus 10.

Referring to FIGS. 1 to 4, the display apparatus 10 of this embodiment can include a display panel 100 and a driving circuit portion that drives the display panel 100. Here, the driving circuit portion can include, for example, a gate driving portion (or gate driving circuit) 210, a data driving portion (or data driving circuit) 220, and a timing control portion (or timing control circuit) 240. In addition, the driving circuit portion can include a power supply portion (or power supply circuit) 280 that supplies power required for driving the display panel 100, the gate driving portion 210, the data driving portion 220, and the timing control portion 240.

Furthermore, the driving circuit portion can include a comparison circuit 250 that compares lock signals, i.e. output lock signals (LCK_out: LCK_out1 and LCK_out2) output from the data driving portion 220 of the double bank structure, synchronizes the output lock signals to generate a synchronous lock signal LCKS, and provides the generated synchronous lock signal LCKS to the timing control portion 240. Here, a potential of the lock signals can be, for example, lower than gate high voltages VGH and VEH and lower than a source driving voltage (SVDD of FIG. 6), but not limited thereto.

The display panel 100 can include a display region AA that displays an image, and a non-display region NA arranged outside the display region AA (or surrounding the display region AA).

In the display region AA, a plurality of pixels P can be arranged in a matrix form along a plurality of horizontal lines (or row lines) and a plurality of vertical lines (or column lines).

Here, the plurality of pixels P can include pixels that display different colors, for example, red, green, and blue pixels that display red, green, and blue, respectively, but not limited thereto.

In the display panel 100, various signal lines that transmit driving signals for driving the pixels P can be formed on a substrate.

In this regard, for example, a plurality of data lines DL that transmit data signals (or data voltages) which are image signals can extend in the vertical direction and be connected to the pixels P of the respective vertical lines.

In addition, a gate line GL that transmits a gate signal (or gate voltage) can extend in the horizontal direction and be connected to the pixels P of the corresponding horizontal line.

In this embodiment, a plurality of gate signals may be used to drive each pixel P, for example, a first scan signal SC1 to a fourth scan signal SC4 and an emission control signal EM can be used. Accordingly, a plurality of gate lines GL respectively transmitting the plurality of gate signals can be used, for example, a first scan line SCL1 to a fourth scan line SCL4 and an emission control line EML can be used.

As such, the plurality of pixels P can be defined by the plurality of data lines DL and gate lines GL intersecting each other.

Each pixel P can include a light emitting diode OD as a light emitting element, and a plurality of transistors and at least one capacitor for driving the light emitting diode OD.

Meanwhile, in this embodiment, for convenience of explanation, 8 transistors and 1 capacitor (8T1C) structure in which the pixel P is equipped with eight transistors T1 to T7 and DT and one capacitor Cst as illustrated in FIG. 2 is taken as an example.

Referring to FIG. 2, the pixel P can include a plurality of switching transistors, for example, first transistor T1 to seventh transistor T7, a driving transistor DT, a storage capacitor Cst, and the light emitting diode OD.

Each of the first to seventh transistors TI to T7 and the driving transistor DT can include a first electrode, a second electrode, and a gate electrode. One of the first electrode and the second electrode can be a source electrode, and the other of the first electrode and the second electrode can be a drain electrode.

Each of the first to seventh transistors T1 to T7 and the driving transistor DT can be a P-type or N-type transistor. Meanwhile, in FIG. 2, the second, third, fourth, fifth, and sixth transistors T2, T3, T4, T5, and T6 are configured as P-type transistors, the first and seventh transistors T1 and T7 are configured as N-type transistors, and the driving transistor DT is configured as a P-type transistor, but not limited thereto. Alternatively, the driving transistor DT can be configured as an N-type transistor.

The first transistor T1 to the seventh transistor T7 and the driving transistor DT can include semiconductors of the same material or can include semiconductors of different materials. In this regard, for example, some of the first transistor Tl to the seventh transistor T7 and the driving transistors DT can have one semiconductor layer among a polycrystalline silicon layer, an oxide semiconductor layer, and an amorphous silicon layer, and another some of the first transistor T1 to the seventh transistor T7 and the driving transistors DT can have another semiconductor layer among a polycrystalline silicon layer, an oxide semiconductor layer, and an amorphous silicon layer.

Meanwhile, since an oxide semiconductor has excellent off-current characteristics and has characteristics suitable for a switching transistor, at least one of the first transistor Tl to the seventh transistor T7 can have an oxide semiconductor layer. In addition, since a polycrystalline silicon has excellent mobility, the driving transistor DT can have a polycrystalline silicon layer. In another form, the first transistor Tl to the seventh transistor T7 and the driving transistor DT can be configured, for example, the driving transistor DT can have an oxide semiconductor layer.

Meanwhile, in this embodiment, a case where the first and seventh transistors T1 and T7 include oxide semiconductor layers and the remaining transistors T2 to T6 and DT include polycrystalline silicon layers is taken as an example.

The gate signals provided to a n-th horizontal line of FIG. 2 (more specifically, at least one of an odd horizontal line and an even horizontal line constituting the n-th horizontal line) can be provided from a corresponding n-th stage of the gate driving portion 210. For example, four scan signals, first to fourth scan signals (SC1 to SC4: SC1(n) to SC4(n)) and two emission control signals, first and second emission control signals (EM: EM1(n), EM2(n)) can be provided. In this case, in the display region AA, first to fourth scan lines SCL1 to SCL4 and first and second emission control lines EML1 and EML2 that are connected to the n-th stage and transmit the first to fourth scan signals SC1(n) to SC4(n) and the first and second emission control signals EM1(n) and EM2(n) to the pixel P can be arranged. Alternatively, the gate driving portion 210 can be configured to provide one emission control signal instead of the two emission control signals EM1(n) and EM2(n).

The first transistor T1 can function as a sampling transistor, the second transistor T2 can function as a data supply transistor, the third and fourth transistors T3 and T4 can function as emission control transistors, the fifth transistor T5 can function as a bias transistor, the sixth transistor T6 can function as a reset transistor (or a first initialization transistor), and the seventh transistor T7 can function as an initialization transistor (or a second initialization transistor).

The light emitting diode OD can include an anode electrode and a cathode electrode. The anode electrode of the light emitting diode OD can be connected to a fifth node N5, and the cathode electrode of the light emitting diode OD can be applied with a low-potential driving voltage EVSS.

The driving transistor DT can include a first electrode connected to a second node N2, a second electrode connected to a third node N3, and a gate electrode connected to a first node N1. The driving transistor DT can provide a driving current to the light emitting diode OD based on a voltage of the first node N1 (i.e., the data voltage Vdata stored in the storage capacitor Cst).

The first transistor T1 can include a first electrode connected to the first node N1, a second electrode connected to the third node N3, and a gate electrode receiving the first scan signal SC1(n). The first transistor Tl can be turned on in response to the first scan signal SC1(n), and the data voltage Vdata can be applied (or written or sampled) to the gate electrode of the driving transistor DT.

The storage capacitor Cst can be connected between the first node N1 and a fourth node N4. The storage capacitor Cst can store or maintain a high-potential driving voltage EVDD.

The second transistor T2 can include a first electrode connected to the data line DL (or, receiving the data voltage Vdata), a second electrode connected to the second node N2, and a gate electrode receiving the second scan signal SC2(n). The second transistor T2 can be turned on in response to the second scan signal SC2(n) and transmit the data voltage Vdata to the second node N2.

The third transistor T3 and the fourth transistor T4 (or first and second emission control transistors) can be connected between a power line of the high-potential driving voltage EVDD and the light emitting diode OD and can form a current path along which the driving current generated by the driving transistor DT moves.

The third transistor T3 can include a first electrode connected to the fourth node N4 and receiving the high-potential driving voltage EVDD, a second electrode connected to the second node N2, and a gate electrode receiving the first emission control signal EM1(n).

The fourth transistor T4 can include a first electrode connected to the third node N3, a second electrode connected to the fifth node N5 (or the anode electrode of the light emitting diode OD), and a gate electrode receiving the second emission control signal EM2(n).

The third and fourth transistors T3 and T4 can be turned on in response to the first and second emission control signals EM1(n) and EM2(n), and the driving current can be supplied to the light emitting diode OD, and the light emitting diode OD can emit light with a luminance corresponding to the driving current.

The fifth transistor T5 can include a first electrode connected to a bias voltage line VobsL that transmits a bias voltage Vobs, a second electrode connected to the second node N2, and a gate electrode that receives the third scan signal SC3(n).

The sixth transistor T6 can include a first electrode connected to a reset voltage line (or a first initialization voltage line) VarL that transmits an anode reset voltage (or a first initialization voltage) Var, a second electrode connected to the fifth node N5, and a gate electrode that receives the third scan signal SC3(n).

The fifth and sixth transistors T5 and T6 can be turned on in response to the third scan signal SC3(n), the bias voltage Vobs can be applied to the second node N2, and the anode reset voltage Var can be applied to the fifth node N5 (i.e., the anode electrode of the light emitting diode OD).

The seventh transistor T7 can include a first electrode connected to an initialization voltage line ViniL that transmits an initialization voltage Vini, a second electrode connected to the first node N1, and a gate electrode that receives the fourth scan signal SC4(n). The seventh transistor T7 can be turned on in response to the fourth scan signal SC4(n) and can apply the initialization voltage Vini to initialize the gate electrode of the driving transistor DT. Unnecessary charges can remain in the gate electrode of the driving transistor DT due to the high-potential driving voltage EVDD applied to the storage capacitor Cst. Thus, by applying the initialization voltage Vini to the gate electrode of the driving transistor DT through the seventh transistor T7, the remaining charges can be initialized.

The 8TIC structure of the pixel P described above is an example, and the pixel P of this embodiment can be configured with a different structure.

Referring to FIG. 1, the timing control portion 240 can process image data Do input from a host system to be suitable for size and resolution of the display panel 100 and supply them to the data driving portion 220. The timing control portion 240 can generate a gate control signal GCS and a data control signal DCS using synchronization signals input from the host system, for example, a dot clock signal CLK, a data enable signal DE, a horizontal synchronization signal HSY, and a vertical synchronization signal VSY. By supplying the gate control signal GCS and the data control signal DCS generated in this way to the gate driving portion 210 and the data driving portion 220, respectively, the gate driving portion 210 and the data driving portion 220 can be controlled.

The timing control portion 240 can be configured by being combined with various processors, for example, a microprocessor, a mobile processor, an application processor, etc., depending on a device to be mounted.

Meanwhile, the host system can be, for example, a driving system that drives an electronic device to which the display apparatus 10 is applied. The electronic device can be, for example, one of a TV (television), a navigation system, a monitor, a mobile device, and a wearable device.

The gate driving portion 210 can receive the gate control signal GCS from the timing control portion 240, generate the gate signals, and sequentially apply the gate signals to the gate lines GL. For example, the gate signals can be sequentially output from the top to the bottom in the vertical direction.

The gate driving portion 210 can be arranged, for example, on at least one side of the display region AA. In this embodiment, a case is taken as an example in which the gate driving portion 210 is configured to include first and second gate driving portions 211 and 212 arranged on both sides of the display region AA, for example, on the left and right sides of the display region AA.

The gate driving portion 210 can be formed directly in the non-display region NA on the substrate of the display panel 100, for example, in a GIP (gate-in panel) structure. In this case, the gate driving portion 210 can be formed during processes of forming elements of the display panel 100.

The gate driving portion 210 configured with the GIP structure can include, for example, a first scan driving circuit that sequentially outputs the first scan signals SC1, a second scan driving circuit that sequentially outputs the second scan signals SC2, a third scan driving circuit that sequentially outputs the third scan signals SC3, a fourth scan driving circuit that sequentially outputs the fourth scan signal SC4, a first emission driving circuit that sequentially outputs the first emission control signals EM1, and a second emission driving circuit that sequentially outputs the second emission control signals EM2.

Each of the first scan driving circuit to the fourth scan driving circuit and the first and second emission driving circuits can be configured with a shift register including a plurality of stages that output respective signals.

The gate driving portion 210 is described with further reference to FIG. 3. FIG. 3 illustrates a part of the gate driving portion 210, and for convenience of explanation, a configuration of a portion of the gate driving portion 210 that drives the n-th horizontal line configured with a n-th odd horizontal line (or 2n-1-th horizontal line) and a n-th even horizontal line (or 2n-th horizontal line) of the display region AA is illustrated.

In the first gate driving portion 211 of the gate driving portion 210, for example, first, third, and fourth scan stages SSC1(n), SSC3(n), and SSC4(n) that constitute the first, third, and fourth scan driving circuits, respectively, first and second emission stages SEM1(n) and SEM2(n) that constitute the first and second emission driving circuits, respectively, and odd and even second scan stages SSC2_O(n) and SSC2_E(n) that constitute the second scan driving circuit can be arranged.

In addition, in the second gate driving portion 212 of the gate driving portion 210, for example, the first, third, and fourth scan stages SSC1(n), SSC3(n), and SSC4(n) that constitute the first, third, and fourth scan driving circuits, respectively, the first and second emission stages SEM1(n) and SEM2(n) that constitute the first and second emission driving circuits, respectively, and the odd and even second scan stages SSC2_O(n) and SSC2_E(n) that constitute the second scan driving circuit can be arranged.

The arrangement of the first to fourth scan stages SSC1(n) to SSC4(n) and the first and second emission stages SEM1(n) and SEM2(n) shown in FIG. 3 is an example, and they can be arranged in various combinations in the first and second gate driving portions 211 and 212.

The first scan stage SSC1(n) can generate the first scan signal SC1(n) and output it to the corresponding first scan line SCL1. Accordingly, the pixel P_O(n) of the n-th odd horizontal line and the pixel P_E(n) of the n-th even horizontal line can be commonly applied with the first scan signal SC1(n).

The odd second scan stage SSC2_O(n) can generate an odd second scan signal SC2_O(n) and output it to the corresponding odd second scan line SCL2, and the even second scan stage SSC2_E(n) can generate an even second scan signal SC2_E(n) and output it to the corresponding even second scan line (SCL2). Accordingly, the pixel P_O(n) of the n-th odd horizontal line can be applied with the odd second scan signal SC2_O(n), and the pixel P_E(n) of the n-th even horizontal line can be applied with the even second scan signal SC2_E(n). Here, the odd second scan signal SC2_O(n) and the even second scan signal SC2_E(n) can have different timings. For example, the odd second scan signal SC2_O(n) and the even second scan signal SC2_E(n) can be applied to a data writing period of the n-th odd horizontal line and a data writing period of the n-th even horizontal line immediately following it, respectively.

The third scan stage SSC3(n) can generate the third scan signal SC3(n) and output it to the corresponding third scan line SCL3. Accordingly, the pixels P_O(n) and P_E(n) of the n-th odd and even horizontal lines can be commonly applied with the third scan signal SC3(n).

The fourth scan stage SSC4(n) can generate the fourth scan signal SC4(n) and output it to the corresponding fourth scan line SCLA. Accordingly, the pixels P_O(n) and P_E(n) of the n-th odd and even horizontal lines can be commonly applied with the fourth scan signal SC4(n).

The first emission stage SEM1(n) can generate the first emission control signal EM1(n) and output it to the corresponding first emission control line EML1. Accordingly, the pixels P_O(n) and P_E(n) of the n-th odd and even horizontal lines can be commonly applied with the first emission control signal EM1(n).

The second emission stage SEM2(n) can generate the second emission control signal EM2(n) and output it to the corresponding second emission control line EML2. Accordingly, the pixels P_O(n) and P_E(n) of the n-th odd and even horizontal lines can be commonly applied with the second emission control signal EM2(n).

Meanwhile, referring to FIG. 3, the bias voltage line VobsL, the reset voltage line VarL, and the initialization voltage line ViniL can be arranged between the gate driving portion 210 and the display region AA.

The bias voltage line VobsL, the reset voltage line VarL, and the initialization voltage line ViniL can respectively supply the bias voltage Vobs, the anode reset voltage Var, and the initialization voltage Vini from the power supply portion 280 to the pixels P within the display region AA.

In FIG. 3, each of the bias voltage line VobsL, the reset voltage line VarL, and the initialization voltage line ViniL is illustrated as being located only on the left or right side of the display region AA, but not limited thereto, and each of the bias voltage line VobsL, the reset voltage line VarL, and the initialization voltage line ViniL can be located on both sides, and even if located on one side, the location on the left or right side is not limited.

Furthermore, referring to FIG. 3, one or more optical regions OA1 and OA2 can be disposed in the display region AA.

The one or more optical regions OA1 and OA2 can be arranged to overlap one or more optical electronic devices, for example, a photographing device such as a camera (or image sensor), and/or a detection sensor such as a proximity sensor and an illuminance sensor. For the operation of the optical electronic device, the one or more optical regions OAl and OA2 can have a light-transmitting structure formed therein and can have transmittance of a certain level or higher. In other words, a number of pixels P per unit area in the one or more optical regions OA1 and OA2 can be smaller than a number of pixels P per unit area in a regular region excluding the optical regions OA1 and OA2 in the display region AA. That is, a resolution of the one or more optical regions OA1 and OA2 can be lower than a resolution of the regular region within the display region AA.

Referring back to FIG. 1, the data driving portion 220 can receive the image data Do and the data control signal DCS from the timing control portion 240, and in response to the data control signal DCS, the data driving portion 220 can convert the image data Do into analog image data i.e., data voltages Vdata, and outputs them to the respective data lines DL.

The data driving portion 220 can be configured as a double bank structure that outputs the data voltage Vdata to both ends of the data line DL.

In this regard, the data driving portion 220 can be configured with a first data driving portion 221 arranged on (or connected to) one side of the display panel 100 (or display region AA), for example, on an upper side (or top), and a second data driving portion 222 arranged on (or connected to) on the other side of the display panel 100, for example, on a lower side (or bottom).

Each of the first and second data driving portions 221 and 222 can be configured to include at least one data IC. In this case, the data IC can be connected to the non-display region NA on the corresponding one side of the display panel 100 while mounted on a flexible circuit film, or can be mounted directly on the non-display region NA.

The first and second data driving portions 221 and 222 can be formed with, for example, channels (or output channels) that are respectively connected to the plurality of data lines DL provided in the display panel 100. In this regard, the first data driving portion 221 can be provided with the channel that outputs the data voltage Vdata to the top of each data line DL. In addition, the second data driving portion 222 can be provided with the channel that outputs the data voltage Vdata to the bottom of each data line DL.

As such, the image data Do output from the timing control portion 240 can be provided in common (or identically) to the first and second data driving portions 221 and 222 that are respectively disposed on the upper and lower sides of the display panel 100.

Accordingly, the same data voltage Vdata output from the first and second data driving portions 221 and 222 can be applied to the top and bottom of each data line DL.

As such, in the double bank structure, since the data line DL can receive the same data voltage Vdata at both ends, the data voltage Vdata can be stably supplied into the display region AA.

The power supply portion 280 can generate DC power required for driving the pixel array and the driving circuit portion of the display panel 100 using, for example, a DC-DC converter. The DC-DC converter can include a charge pump, a regulator, a buck converter, a boost converter, etc.

The power supply portion 280 can receive, for example, a power voltage Vcc that is a driving voltage for driving the display apparatus (10) from the host system and generate the DC voltages such as the gate low voltages VGL and VEL, the gate high voltages VGH and VEH, the high-potential driving voltage EVDD, the low-potential driving voltage EVSS, and the source driving voltage (SVDD in FIG. 6). The gate low voltages VGL and VEL and the gate high voltages VGH and VEH can be supplied to the gate driving portion 210. The high-potential driving voltage EVDD and the low-potential driving voltage EVSS can be supplied in common to the pixels P in the display panel 100. The source driving voltage SVDD can be supplied to the first and second data driving portions 221 and 222 constituting the data driving portion 220.

Here, the source driving voltage SVDD can have a potential that is higher than the high-potential driving voltage EVDD and lower than the gate high voltages VGH and VEH, but not limited thereto. In addition, the low-potential driving voltage EVSS can have a potential that is, for example, lower than, equal to, or higher than the gate low voltages VGL and VEL.

The gate signals applied to the pixel P of the display panel 100 is be described with further reference to FIG. 4. Meanwhile, in FIG. 4, for convenience of explanation, the first and second emission control signals EM(n) are not individually illustrated, but rather one emission control signal EM(n) representing them is illustrated as an example.

A frame (or refresh frame) in which data is written and an image is refreshed can be divided into a non-emission period Tne and an emission period Te.

The non-emission period Tne and the emission period Te can be defined by the emission control signal EM(n). In this regard, a scan pulse section of a high level, as a turn-off level, of the emission control signal EM(n) (e.g., the first and second emission control signals EM1(n) and EM2(n)) can correspond to the non-emission period Tne, and a section of a low level, as a turn-on level, of the emission control signal EM(n) (e.g., the first and second emission control signals EM1(n) and EM2(n)) can correspond to the emission period Te.

In the non-emission period Tne, an operation in which the data voltage Vdata is applied and written can be performed.

In this regard, for example, during the data writing period (or sampling period) Ts when each of the odd and even second scan signals SC2_O(n) and SC2_E(n) is applied, more specifically, a scan pulse of a low level, as a turn-on level, of each of the odd and even second scan signals SC2_O(n) and SC2_E(n) is applied, the data voltage Vdata of each of the odd and even pixels P_O(n) and P_E(n) can be applied and written to the gate electrode of the driving transistor DT. Meanwhile, in the data writing period Ts, a threshold voltage of the driving transistor DT can be sampled and reflected to the gate electrode of the driving transistor DT.

In the data writing period Ts, the first scan signal SC1(n) can have a scan pulse of a high level, which is a turn-on level, so that the first transistor T1 can have a turn-on state.

Meanwhile, in the non-emission period Tne, at least one bias period (or anode reset period) Tobs when the bias voltage Vobs and the anode reset voltage Var are applied can be located. In this embodiment, a case where the bias periods Tobs are set before and after the data writing period Ts is taken as an example. In this case, for convenience of explanation, the bias period Tobs set before the data writing can be referred to as a first bias period Tobs1, and the bias period Tobs set after the data writing can be referred to as a second bias period Tobs2.

In each of the first and second bias periods Tobs1 and Tobs2, the third scan signal SC3(n) can have a scan pulse of a low level which is a turn-on level.

In this case, the fifth transistor T5 can be turned on, so that the bias voltage Vobs can be applied to the second node N2 and the third node N3. Through this, an on-bias stress operation for the driving transistor DT can be performed.

In addition, the sixth transistor T6 can be turned on, so that the anode reset voltage Var can be applied to the fifth node N5. Through this, an anode reset operation for the anode electrode of the light emitting diode OD can be performed.

Meanwhile, an operation of applying the initialization voltage Vini can be performed between the data writing period Ts and the first bias period Tobs1. In this initialization section Ti, the fourth scan signal SC4(n) can have a scan pulse of a high level which is a turn-on level. Accordingly, the seventh transistor T7 can be turned on, so that the initialization voltage Vini can be applied to the first node N1 i.e., the gate electrode of the driving transistor DT. Through this, an initialization operation for the driving transistor DT can be performed.

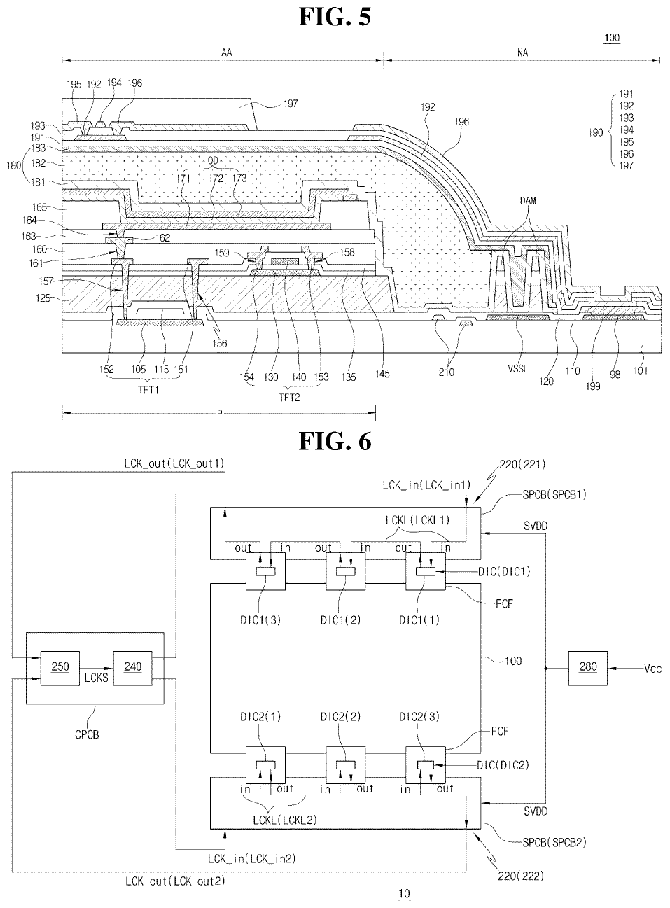

Hereinafter, an example of a cross-sectional structure of the display panel 100 of this embodiment is described with further reference to FIG. 5. FIG. 5 is a cross-sectional view schematically illustrating an example of a cross-sectional structure of a display panel according to an embodiment of the present disclosure.

In FIG. 5, for convenience of explanation, two thin film transistors TFT1 and TFT2 are illustrated in the pixel P within the display region AA. Here, the thin film transistor TFT1 positioned relatively lower and closer to the substrate 101 is referred to as a first thin film transistor TFT1, which can be a polycrystalline silicon thin film transistor. The thin film transistor TFT2 positioned relatively upper and farther from the substrate 101 is referred to as a second thin film transistor TFT2, which can be an oxide thin film transistor.

Meanwhile, the first thin film transistor TFT1 can be a driving transistor (DT of FIG. 2), but not limited thereto, and in FIG. 5, for convenience of explanation, a case in which the first thin film transistor TFT1 is connected to the light emitting diode OD is illustrated. In addition, the second thin film transistor TFT2 can be one of the first to seventh transistors (T1 to T7 of FIG. 2) that are switching thin film transistors, more specifically, the first transistor T1 connected to the storage capacitor Cst, but not limited thereto.

The substrate 101 can be configured as, for example, a thin glass substrate (or glass film) or a plastic substrate (or plastic film) so as to implement flexible characteristics of the display panel 100.

Here, in a case where the substrate 101 is configured as a glass substrate, for example, the substrate 101 can have a thickness of approximately 0.2 mm.

Meanwhile, in a case where the substrate 101 is configured as a plastic substrate, for example, the substrate 101 can include at least one polyimide layer.

The first thin film transistor TFT1 can include a first semiconductor layer 105 disposed on the substrate 101, a first gate electrode 115 overlapping the semiconductor layer 105 with a first insulating layer 110 interposed therebetween, and a first source electrode 151 and a first drain electrode 152 located on a fourth insulating layer 145 over the first gate electrode 115. Here, the first semiconductor layer 105 can be formed of polycrystalline silicon, but not limited thereto.

The first semiconductor layer 105 can include a central channel region and source and drain regions on both sides thereof. The first source electrode 151 and the first drain electrode 152 can be connected to the source region and the drain region of the first semiconductor layer 105 through the first and second contact holes 156 and 157 that are formed in the insulating layers 110, 120, 125, 135, and 145 located below the first source electrode 151 and the first drain electrode 152.

A second insulating layer 120 can be formed on the first gate electrode 115 of the first thin film transistor TFT1.

A first interlayered insulating layer 125 can be formed on the second insulating layer 120. The second thin film transistor TFT2 can be formed on the first interlayered insulating layer 125.

The second thin film transistor TFT2 can include a second semiconductor layer 130 on the first interlayered insulating layer 125, a second gate electrode 140 overlapping the second semiconductor layer 130 with a third insulating layer 135 interposed therebetween, and a second source electrode 153 and a second drain electrode 154 located on the fourth insulating layer 145 over the second gate electrode 140. Here, the second semiconductor layer 130 can be formed of an oxide semiconductor, but not limited thereto.

The second semiconductor layer 130 can include a central channel region and source and drain regions on both sides thereof. The second source electrode 153 and the second drain electrode 154 can be connected to the source and drain regions of the second semiconductor layer 130 through third and fourth contact holes 158 and 159 formed in the insulating layers 135 and 145 located below the second source electrode 153 and the second drain electrode 154.

A second interlayered insulating layer (or first planarization layer) (160) can be formed on the second thin film transistor TFT2.

Here, the first, second, third, and fourth insulating layers 110, 120, 135, and 145 can be formed of an inorganic insulating material such as silicon nitride or silicon oxide, but not limited thereto.

In addition, the first and second interlayered insulating layers 125 and 160 can be formed of an organic insulating material such as photo acrylic or benzocyclobutene, but not limited thereto.

A connection electrode 162 can be formed on the second interlayered insulating layer 160. The connection electrode 162 can be connected to the first drain electrode 152 through a contact hole 161 formed in the second interlayered insulating layer 160.

A third interlayered insulating layer (or second planarization layer) 163 can be formed on the connection electrode 162. The third interlayered insulating layer 163 can be formed of an organic insulating material such as photo acrylic or benzocyclobutene, but not limited thereto.

The light emitting diode OD and a bank 165 can be formed on the third interlayered insulating layer 163.

The light emitting diode OD can include an anode electrode (or first electrode) 171, a light emitting layer 172, and a cathode electrode (or second electrode) 173.

The anode electrode 171 can be connected to the connection electrode 162 through the contact hole 164 formed in the third interlayered insulating layer 163.

The bank 165 can be disposed along a boundary of the pixel P and can be formed to cover an edge of the anode electrode 171. The light emitting layer 172 can be formed on the anode electrode 171 exposed through an opening of the bank 165.

The cathode electrode 173 can be formed on the light emitting layer 172 and can be applied with the low-potential driving voltage (EVSS of FIG. 2).

An encapsulation layer 180 can be formed on the cathode electrode 173. The encapsulation layer 180 can include at least one inorganic encapsulation layer and at least one organic encapsulation layer, but not limited thereto. In this disclosure, a structure of the encapsulation layer 180, in which a first encapsulation layer 181, a second encapsulation layer 182, and a third encapsulation layer 183 are sequentially stacked, is described as an example.

The first encapsulation layer 181 can be formed on the substrate 101 on which the cathode electrode 173 is formed. The third encapsulation layer 183 can be formed on the substrate 101 on which the second encapsulation layer 182 is formed, and can be formed to surround an upper surface, a lower surface, and a side surface of the second encapsulation layer 182 together with the first encapsulation layer 181. The first encapsulation layer 181 and the third encapsulation layer 183 can minimize or prevent external moisture or oxygen from penetrating into the light emitting diode OD. The first encapsulation layer 181 and the third encapsulation layer 183 can be formed of an inorganic insulating material capable of low-temperature deposition, such as silicon nitride, silicon oxide, silicon oxynitride, or aluminum oxide.

The second encapsulating layer 182 can act as a buffer to relieve stress between layers due to bending of the display apparatus 10 and can flatten steps between layers. The second encapsulation layer 182 can be formed on the substrate 101 on which the first encapsulation layer 181 is formed, using a non-photosensitive organic insulating material such as acrylic resin, epoxy resin, phenolic resin, polyamide resin, polyimide resin, polyethylene, or silicon oxycarbon (SiOC), or a photosensitive organic insulating material such as photo acrylic, but not limited thereto. When the second encapsulation layer 182 is formed through an inkjet method, a dam DAM can be placed in the non-display region NA to prevent the second encapsulation layer 182 in liquid form from spreading to an edge of the substrate 101. The dam DAM can be disposed closer to the edge of the substrate 101 than the second encapsulation layer 182. By the dam DAM, the second encapsulation layer 182 can be prevented from spreading to a pad region, where a conductive pad is disposed, on an outermost edge of the substrate 101.

The dam DAM can be designed to prevent or at least reduce the spreading of the second encapsulation layer 182, but if the second encapsulation layer 182 is formed to exceed a height of the dam DAM during a process, the second encapsulation layer 182 as an organic layer can be exposed to an outside, so that moisture, etc. can easily penetrate into the light emitting element. To prevent this, 10 or more dam DAM can be formed in succession, but not limited thereto.

The dam DAM can be formed simultaneously with the first interlayered insulating layer 125, the second interlayered insulating layer 160, and the third interlayered insulating layer 163. When forming the first interlayered insulating layer 125, a lower layer of the dam DAM can be formed together, and when forming the second and third interlayered insulating layers 160 and 163, an upper layer of the dam DAM can be formed together, so that the dam DAM can be formed in a triple laminated structure. As another example, the dam DAM can be formed with one or two of the first, second, and third interlayered insulating layers 125, 160, and 163.

Accordingly, the dam DAM can be formed of the same material as the first interlayered insulating layer 125, the second interlayered insulating layer 160, and the third interlayered insulating layer 163, but not limited thereto.

The dam DAM can be formed to overlap a low-potential driving voltage line VSSL. For example, the low-potential driving voltage line VSSL can be formed at a lower layer of a region, where the dam DAM is located, in the non-display region NA.

The low-potential driving voltage line VSSL and the gate driving portion 210 configured in the GIP structure can be formed along a periphery of the display panel 100, and the low-potential driving voltage line VSSL can be located outside the gate driving portion 210. In addition, the low-potential driving voltage line VSSL can be connected to the cathode electrode 173 to apply the low-potential driving voltage EVSS. The gate driving portion 210 is simply shown in a planar and cross-sectional manner in the drawings, but can be configured with the same structure as the first thin film transistor TFT1 and/or the second thin film transistor TFT2 of the display region AA.

A touch layer (or touch element layer) 190 can be disposed on the encapsulation layer 180. In the touch layer 190, a touch buffer layer 191 can be positioned between a touch sensor metal including touch electrode connection lines 192 and 194 and touch electrodes 195 and 196, and the cathode electrode 173 of the light emitting diode OD.

The touch buffer layer 191 can block a chemical solution (developer, etchant, etc.) used in a manufacturing process of the touch sensor metal disposed on the touch buffer layer 191 or moisture from the outside from penetrating into the light emitting layer 172 containing an organic material. Accordingly, the touch buffer layer 191 can prevent damage to the light emitting layer 172 that is vulnerable to the chemical solution or moisture.

According to a mutual-capacitance-based touch sensor structure, the touch electrodes 195 and 196 can be disposed on the touch buffer layer 191, and the touch electrodes 195 and 196 can be arranged to cross each other.

The touch electrode connection lines 192 and 194 can electrically connect the touch electrodes 195 and 196. One of the touch electrode connection lines 192 and 194, and the touch electrodes 195 and 196 can be located at different layers with a touch insulation layer 193 interposed therebetween. In addition, one of the touch electrode connection lines 192 and 194 and the other of the touch electrode connection lines 192 and 194 can be located at different layers with the touch insulation layer 193 interposed therebetween.

The touch electrode connection lines 192 and 194 can be arranged to overlap the bank 165, thereby preventing a decrease in aperture ratio, but not limited thereto.

Meanwhile, a part of the touch electrodes 195 and 196 and a part of the touch electrode connection line 192 can extend along the top and side surfaces of the encapsulation layer 180 and the top and side surfaces of the dam DAM and be electrically connected to a touch driving circuit through a touch pad 198 and 199.

A part of the touch electrodes 195 and 196 and a part of the touch electrode connection line 192 can receive a touch driving signal from the touch driving circuit and transmit it to the touch electrodes 195 and 196 and can transmit a touch sensing signal detected by the touch electrodes 195 and 196 to the touch driving circuit.

In this regard, for example, a driving IC (e.g., data IC, etc.) of the data driving portion 220 including the touch driving circuit can be configured in a Chip on Film (COF) type and connected to the non-display region NA of the substrate 101 of the display panel 100, and in this case, an end of the touch pad 198 and 199 can be connected to a flexible circuit film on which the driving IC is mounted, so that a signal can be transmitted.

A touch protective layer 197 can be disposed on the touch electrodes 195 and 196. In the drawing, the touch protective layer 197 is shown as being disposed only on the touch electrodes 195 and 196, but not limited thereto, and the touch protective layer 197 can extend before or after the dam DAM to be disposed on the touch electrode connection line 192.

In addition, a color filter can be disposed on the encapsulation layer 180. The color filter can be positioned on the touch layer 190, or between the encapsulation layer 180 and the touch layer 190.

As described above, since the display apparatus 10 of this embodiment can use the data driving portion 220 of a double bank structure, the same lock signal (or lock voltage), i.e. input lock signal (LCK_in: LCK_in1 and LCK_in2) can be input to each of the first and second data driving portions 221 and 222 of the data driving portion 220, and a clock training i.e., a clock recognition process can be performed in the first and second data driving portions 221 and 222. When the clock training is completed (or succeeded), each of the first and second data driving portions 221 and 222 can generate an output lock signal LCK_out as a feedback signal for the input lock signal LCK_in.

Here, the clock training can be, for example, a process in which the timing control portion 240 provides a training clock to the first and second data driving portions 221 and 222 and the first and second data driving portions 221 and 222 normally recognize the training clock. The clock training can be performed, for example, during an initial driving time after the display apparatus 10 is powered on and during a blank time between frames.

In this regard, for example, when the power voltage Vcc is input to the power supply portion 280 to drive the display apparatus 10, the power supply portion 280 can generate various driving voltages for driving the display apparatus 10, and the timing control portion 240 can generate and output the lock signal, i.e. the input lock signal LCK_in in synchronization with an input timing of the power voltage Vcc.

As such, the lock signal, i.e. the input lock signal LCK_in output from the timing control portion 240 can be input to the first and second data driving portions 221 and 222 simultaneously. For convenience of explanation, the lock signal, i.e. the input lock signal LCK_in input to the first data driving portion 221 on the upper side can be referred to as an input first lock signal LCK_in1, and the lock signal, i.e. the input lock signal LCK_in input to the second data driving portion 222 on the lower side can be referred to as an input second lock signal LCK_in2.

When the input first and second lock signals LCK_in1 and LCK_in2 are transmitted at the same timing, the first and second data driving portions 221 and 222 can individually perform the clock training.

When the clock training is completed, the first and second data driving portions 221 and 222 can individually generate and output the output lock signal LCK_out.

For example, each of the first and second data driving portions 221 and 222 can be configured with a plurality of data ICs that are connected in a cascade manner and operate sequentially. In this regard, for example, regarding each of the first and second data driving portions 221 and 222, when the plurality of data ICs receive the respective lock signal, i.e. the input lock signal LCK_in input thereto, the plurality of data ICs can sequentially perform a clock training operation, and then generate and output respective lock signals.

In this case, in the first data driving portion 221, the first data IC can perform a clock training according to the input first lock signal LCK_in1, and then generate a corresponding output lock signal and provide it to the second data IC, and in this manner, the last data IC can perform a clock training, and then generate a corresponding output lock signal LCK_out, and the output lock signal LCK_out i.e., the output first lock signal LCK_out1 can be transmitted to the comparison circuit 250. As such, in the first data driving portion 221, the plurality of data ICs can sequentially receive the lock signal and perform the clock training operation, and output the output first lock signal LCK_out1 finally.

Similarly, in the second data driving portion 222, the first data IC can perform a clock training according to the input second lock signal LCK_in2, and then generate a corresponding output lock signal and provide it to the second data IC, and in this manner, the last data IC can perform a clock training, and then generate a corresponding output lock signal LCK_out, and the output lock signal LCK_out i.e., the output second lock signal LCK_out2 can be transmitted to the comparison circuit 250. As such, in the second data driving portion 222, the plurality of data ICs can sequentially receive the lock signal and perform the clock training operation and output the output second lock signal LCK_out2 finally.

As above, the output first lock signal LCK_out1 output from the last data IC of the first data driving portion 221 and the output second lock signal LCK_out2 output from the last data IC of the second data driving portion 222 can be provided to the comparison circuit 250, and the comparison circuit 250 can compare the output first and second lock signals LCK_out1 and LCK_out2.

For example, by comparing the output first and second lock signals LCK_out1 and LCK_out2, the comparison circuit 250 can check whether output timings match or are synchronized between the output first and second lock signals LCK_out1 and LCK_out2 of the first and second data driving portions 221 and 222. In addition, for example, by checking whether either one of the output first and second lock signals LCK_out1 and LCK_out2 is under a lock failure state (for example, by having an abnormal waveform), the comparison circuit 250 can check whether at least one of the first and second data driving portions 221 and 222 has failed the clock training and has caused a lock failure.

The comparison circuit 250 can compare the output first and second lock signals LCK_out1 and LCK_out2 to synchronize lock states of the output first and second lock signals LCK_out1 and LCK_out2, and generate and transmit a synchronized lock signal, i.e. the synchronous lock signal LCKS to the timing control portion 240.

In response to the synchronized lock signal, i.e. the synchronous lock signal LCKS, the timing control portion 240 can control transmission of the image data Do to the first and second data driving portions 221 and 222 to synchronize the output timings of the first and second data driving portions 221 and 222.

In this regard, for example, in a case where one of the output first and second lock signals LCK_out1 and LCK_out2 is delayed compared to the other and thus they are not synchronized with each other (i.e., they are asynchronized with each other), the transmission timing of the image data Do can be adjusted according to the synchronous lock signal LCKS generated based on the delayed output lock signal LCK_out, so that the image data Do can be provided to the first and second data driving portions 221 and 222.

In addition, in a case where one of the first and second data driving portions 221 and 222 has a lock failure, the transmission of the image data Do can be turned off (or stopped) according to the synchronous lock signal LCKS generated by reflecting the lock failure, so that the output operation of the data voltage Vdata of the first and second data driving portions 221 and 222 can be turned off.

As such, the output lock signals of the first and second data driving portions 221 and 222 can be monitored in real time through the comparison circuit 250, and the comparison circuit 250 synchronizes the lock states of the output lock signals, thereby controlling the transmission of the image data Do to the first and second data driving portions 221 and 222.

Accordingly, it is possible to mitigate or prevent occurrence of a potential difference in the data voltage Vdata between the upper and lower ends in the asynchronous section or lock failure section of the upper and lower output lock signals, i.e. the output first and second lock signals LCK_out1 and LCK_out2. Accordingly, it is possible to mitigate or prevent an overcurrent caused by the potential difference in the data voltage Vdata between the upper and lower channels, and to mitigate or prevent the data IC from heating up or burning due to the overcurrent. In addition, it is possible to mitigate or prevent occurrence of poor image quality, such as block dim, due to a long delay of the output lock signal LCK_out.

As such, configuration and method of this embodiment, which compares and synchronizes the output first and second lock signals LCK_out1 and LCK_out2 of the first and second data driving portions 221, 222 at the upper and lower ends to control the transmission of the image data Do to the first and second data driving portions 221 and 222 and to control the output timing of the first and second data driving portions 221 and 222, are described in more detail below.

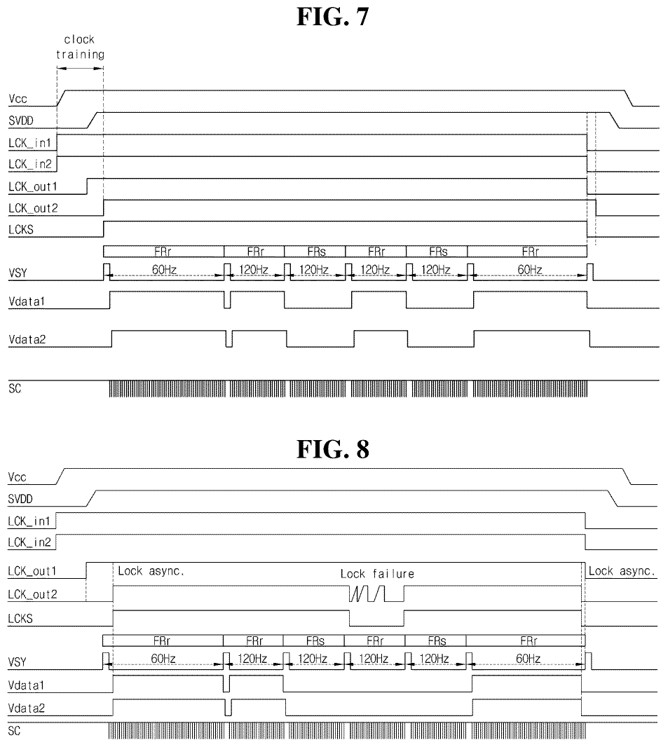

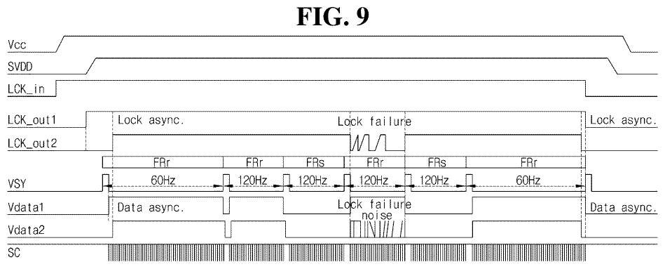

FIG. 6 is a view schematically illustrating a timing control portion, a data driving portion, and a comparison circuit of a display apparatus according to an embodiment of the present disclosure. FIG. 7 is a timing chart schematically illustrating input and output lock signals, a synchronous lock signal, and data voltages according to an embodiment of the present disclosure. FIG. 8 is a timing chart schematically illustrating an example of input and output lock signals, a synchronous lock signal, and data voltages in a case of output lock signals having asynchronization and a lock failure according to an embodiment of the present disclosure. FIG. 9 is a timing chart schematically illustrating input and output lock signals and data voltages in a case of output lock signals having asynchronization and lock failure according to a comparative example.

Referring to FIG. 6 together with FIGS. 1 to 5, the display apparatus 10 of this embodiment can use the data driving portion 220 of a double bank structure. The data driving portion 220 of the double bank structure can include the first data driving portion 221 and the second data driving portion 222 connected to the top and bottom of the display panel 100, respectively.

Meanwhile, the display apparatus 10 of this embodiment can be driven in a VRR (variable refresh rate) method in which a driving frequency i.e., a refresh rate is adjusted to reduce power consumption, thereby implementing low-power driving.

In this regard, referring to FIGS. 7 and 8, a frequency i.e., a refresh rate can be varied during a driving time when the display apparatus 10 is driven by receiving the power voltage Vcc, for example, can be varied between 60 Hz and 120 Hz. Here, a VRR type driving is taken as an example in which when driving at a high speed of 120 Hz, the display panel 100 can be driven by dividing frames into refresh frames FRr in which an image (or data voltages (Vdata: Vdata1, Vdata2)) is refreshed, and a skip frame FRs in which an image is not refreshed and a previous image is maintained as it is, and when driving at a low speed of 60 Hz, the display panel 100 can be driven with the refresh frames FRr. Meanwhile, in FIGS. 7, 8 and 9, “SC” represents scan signals (SC1 to SC4 of FIGS. 2 and 3) output from the gate driving portion 210.

The first and second data driving portions 221 and 222 of the double bank structure can each include, for example, the plurality of data ICs DIC. In this regard, in this embodiment, an example is given in which the first data driving portion 221 includes three first data ICs DIC1 i.e., first to third, first data ICs DIC1(1) to DIC1(3), and the second data driving portion 222 includes three second data ICs DIC2 i.e., first to third, second data ICs DIC2(1) to DIC2(3).

The first and second data driving portions 221 and 222 of the double bank structure can output the same data voltage Vdata for each channel to the upper and lower ends of the corresponding data line DL.

Here, for convenience of explanation, the data voltage Vdata output from the first data driving portion 221 on the upper side can be referred to as a first data voltage (or upper data voltage) Vdata1, and the data voltage Vdata output from the second data driving portion 222 on the lower side can be referred to as the second data voltage (or lower data voltage) Vdata2.

In addition, in this embodiment, a case where the data IC DIC of each of the first and second data driving portions 221 and 222 is mounted on a flexible circuit film FCF in a COF type is taken as an example.

Meanwhile, the first data driving portion 221 can include a first source board SPCB1 that is a source board SPCB to which the plurality of first data ICs DIC1 are connected. Similarly, the second data driving portion 222 can include a second source board SPCB2 that is a source board SPCB to which the plurality of second data ICs DIC2 are connected.

In this regard, signals output from the timing control portion 240 can be transmitted to the first data IC DIC1 via the first source board SPCB1 and can also be transmitted to the second data IC DIC2 via the second source board SPCB2.

Here, a first lock signal line LCKL1, which is a lock signal line LCKL that transmits a lock signal, can be formed in the first source board SPCB1. A second lock signal line LCKL2, which is a lock signal line LCKL that transmits a lock signal, can be formed in the second source board SPCB2.

In this regard, for example, the input first lock signal LCK_in1 output from the timing control portion 240 can be input to the first, first data IC DIC1(1), and the first, first data IC DIC1(1) can perform a clock training to output a lock signal. Next, the lock signal (or a first output lock signal) output from the first, first data IC DIC1(1) can be input to the second, first data IC DIC1(2), and the second, first data IC DIC1(2) can perform a clock training to output a lock signal.

Next, the lock signal (or a second output lock signal) output from the second, first data IC DIC1(2) can be input to the third, first data IC DIC1(3), and the third, first data IC DIC1(3) can perform a clock training to output an output first lock signal LCK_out1. As such, the output first lock signal LCK_out1, which is a lock signal output from the third, first data IC DIC1(3) that is the last of the first data ICs DIC1, can be transmitted to the comparison circuit 250.

As such, in order to transmit the input first lock signal LCK_in1 provided from the timing control portion 240, the output lock signals generated from the first and second, first data ICs DIC1(1) and DIC1(2), and the output first lock signal LCK_out1 generated from the third, first data IC DIC1(3), the first lock signal line LCKL1 can be formed in the first source board SPCB1.

Furthermore, a lock signal line for inputting and outputting the lock signals can also be formed in the flexible circuit film FCF on which the first data IC DIC1 is mounted.

In addition, the input second lock signal LCK_in2 output from the timing control portion 240 can be input to the first, second data IC DIC2(1), and the first, second data IC DIC2(1) can perform a clock training to output a lock signal. Next, the lock signal (or a first output lock signal) output from the first, second data IC DIC2(1) can be input to the second, second data IC DIC2(2), and the second, second data IC DIC2(2) can perform a clock training to output a lock signal. Next, the lock signal (or a second output lock signal) output from the second, second data IC DIC2(2) can be input to the third, second data IC DIC2(3), and the third, second data IC DIC2(3) can perform a clock training to output an output second lock signal LCK_out2. As such, the output second lock signal LCK_out2, which is a lock signal output from the third, second data IC DIC2(3) that is the last of the second data ICs DIC2, can be transmitted to the comparison circuit 250.

As such, in order to transmit the input second lock signal LCK_in2 provided from the timing control portion 240, the output lock signals generated from the first and second, second data ICs DIC2(1) and DIC2(2), and the output second lock signal LCK_out2 generated from the third, second data IC DIC2(3), the second lock signal line LCKL2 can be formed in the second source board SPCB2.

Furthermore, a lock signal line for inputting and outputting the lock signals can also be formed on the flexible circuit film FCF on which the second data IC DIC2 is mounted.

Meanwhile, the timing control portion 240 and the comparison circuit 250 can be mounted on, for example, a control board CPCB, but not limited thereto.

The timing control portion 240 can provide the input first lock signal LCK_inl and the input second lock signal LCK_in2, which are the same input lock signal LCK_in, to the first data driving portion 221 and the second data driving portion 222, respectively.

Regarding the input first and second lock signals LCK_in1 and LCK_in2, referring to FIG. 7, for example, the input first and second lock signals LCK_in1 and LCK_in2 can be synchronized with each other and be input to the corresponding first and second data driving portions 221 and 222 at the same timing.

In this regard, the input first and second lock signals LCK_in1 and LCK_in2 can have a high level in synchronization with a time when the display apparatus 10 is powered on and the power voltage Vcc is applied to the power supply portion 280. The input first and second lock signals LCK_in1 and LCK_in2 of the high level can be continuously maintained during the driving time of the display apparatus (10) and be input to the first and second data driving portions 221 and 222.

In this regard, referring to FIGS. 7 and 8, the input first and second lock signals LCK_in1 and LCK_in2 can be continuously output from the time of power-on to the last output time (or last frame) of the first and second data driving portions 221 and 222 before power-off.

As such, the input first and second lock signals LCK_in1 and LCK_in2 output from the timing control portion 240 from the time of power-on can be input to the corresponding first and second data driving portions 221 and 222, and the first and second data driving portions 221 and 222 can perform the clock training to output the corresponding output first and second lock signals LCK_out1 and LCK_out2.

For example, in a power-on sequence that is performed for a certain period of time immediately after the display apparatus 10 is powered on, the first and second data driving portions 221 and 222 can perform the clock training and output the output first and second lock signals LCK_out1 and LCK_out2. Furthermore, the clock training can be performed during a blank period between adjacent frames FR, for example, during an output period of the vertical synchronization signal VSY, to output the output first and second lock signals LCK_out1 and LCK_out2.

The output of the output first and second lock signals LCK_out1 and LCK_out2 can start after a certain period of time has passed from the start point of the input first and second lock signals LCK_in1 and LCK_in2. In addition, the output first and second lock signals LCK_out1 and LCK_out2 can be substantially continuously maintained during the driving time of the display apparatus 10.

In this regard, referring to FIG. 7, in a normal driving state of the display apparatus 10, the output first and second lock signals LCK_out1 and LCK_out2 can be continuously output from a certain time after the power-on time to the last output time (or last frame) of the first and second data driving portions 221 and 222 before the power-off time.

The comparison circuit 250 can receive the output first and second lock signals LCK_out1 and LCK_out2 output from the first and second data driving portions 221 and 222, compare the states of the output first and second lock signals LCK_out1 and LCK_out2, synchronize their lock states, and generate the synchronous lock signal LCKS.

In this regard, for example, the comparison circuit 250 can compare the output first and second lock signals LCK_out1 and LCK_out2 to check whether the output timings are synchronized and match, or asynchronized and mismatch, and if asynchronized, synchronize the lock states.

In this regard, referring to FIGS. 7 and 8, for example, in the power-on sequence, the output first lock signal LCK_out1 can be output first and then the output second lock signal LCK_out2 can be delayed and output. Conversely, in the power-on sequence, the output second lock signal LCK_out2 can be output first and then the output first lock signal LCK_out1 can be delayed and output.

As such, the output delay of one of the output first and second lock signals LCK_out1 and LCK_out2 can be caused by a resistor-capacitor (RC) component of a line transmitting the lock signal, external factors, etc. In this regard, for example, a signal transmission line between the input of the input first lock signal LCK_in1 and the output of the output first lock signal LCK_out1 and a signal transmission line between the input of the input second lock signal LCK_in2 and the output of the output second lock signal LCK_out2 can have different RC resistances, or the output first lock signal LCK_out1 and the output second lock signal LCK_out2 can have different output timings due to external factors.

In addition, referring to FIG. 7, in a power-off sequence of the display apparatus 10, the output first lock signal LCK_out1 can be normally terminated and then the output second lock signal LCK_out2 can be delayed and terminated. Conversely, referring to FIG. 8, in the power-off sequence, the output first lock signal LCK_out1 can be normally terminated, and before this, the output second lock signal LCK_out2 can be terminated.

As such, when one of the output first and second lock signals LCK_out1 and LCK_out2 has a lock state of a high level and the other has a unlock state of a low level i.e., when their lock states do not match and are not synchronized, the comparison circuit 250 can output the synchronous lock signal LCKS that has a low level of an unlock state during such the asynchronized section.

On the contrary, when both the output first and second lock signals LCK_out1 and LCK_out2 have a lock state of a high level, the comparison circuit 250 can output the synchronous lock signal LCKS that has a high level of a lock state during such the same lock section. In this regard, referring to FIGS. 7 and 8, for example, after the delayed output second lock signal LCK_out2 in the power-on sequence is switched to the lock state, the comparison circuit 250 can generate the high-level synchronous lock signal LCKS.

Furthermore, the comparison circuit 250 can compare the output first and second lock signals LCK_out1 and LCK_out2 to determine whether at least one of the first and second data driving portions 221 and 222 is abnormally driven and a lock failure has occurred, and when a lock failure has occurred, and the comparison circuit 250 can synchronize them to match them to an unlock state.

In this regard, referring to FIG. 8, for example, the second data driving portion 222 is abnormally driven in the refresh frame FRr of the 120 Hz driving, causing a lock failure, and accordingly, the output second lock signal LCK_out2 may not maintain a normal high level and may have an abnormal waveform. As such, when a lock failure occurs, the second data driving portion 222 may fail a clock recognition and perform an abnormal output operation, and noise may occur in the second data voltage Vdata2 output from the second data driving portion 222.

As such, when a lock failure occurs in the second data drive portion 222 and the output second lock signal LCK_out2 has an abnormal lock failure state, the comparison circuit 250 can output the low-level synchronous lock signal LCKS of an unlock state during the lock failure section.

As above, the output first and second lock signals LCK_out1 and LCK_out2 can be compared, and when the lock states of these signals are not synchronized with each other or at least one of them has a lock failure state, the comparison circuit 250 can set the synchronous lock signal LCKS to a low level of an unlock state. In addition, when both the output first and second lock signals LCK_out1 and LCK_out2 are in a lock state, the comparison circuit 250 can set the synchronous lock signal LCKS to a high level of a lock state.

As such, the synchronous lock signal LCKS generated by synchronizing the lock states in the comparison circuit 250 can be provided to the timing control portion 240, and the timing control portion 240 can adjust the transmission timing of the image data Do for the first and second data driving portions 221 and 222 according to the synchronous lock signal LCKS.

In this regard, referring to FIG. 8, for example, when the lock states of the output first and second lock signals LCK_out1 and LCK_out2 are not synchronized with each other or at least one of them is in a lock failure state, the synchronous lock signal LCKS can become a low level which is an unlock state, and in response to the unlock state of the synchronous lock signal LCKS, the timing control portion 240 can turn off the transmission of the image data Do to the first and second data driving portions 221 and 222.

In this regard, when the output first and second lock signals LCK_out1 and LCK_out2 are asynchronized, the timing control portion 240 can turn off the transmission of the image data Do during this asynchronized section, and accordingly, the output of the data voltages Vdata1 and Vdata2 of the first and second data driving portions 221 and 222 can be turned off during this asynchronized section.

For example, as shown in FIG. 8, in the power-on sequence, regarding the output second lock signal LCK_out2 delayed compared to the output first lock signal LCK_out1, when the output of the output second lock signal LCK_out2 is delayed until an initial section of the refresh frame FRr of the 60 Hz driving at which the output of the first and second data driving portions 221 and 222 starts, the synchronous lock signal LCKS can be maintained at a low level until the initial section of the refresh frame FRr which is the delayed point in time, and then be switched to a high level.

In addition, as shown in FIG. 8, in the power-off sequence, regarding the output second lock signal LCK_out2 terminated before the output first lock signal LCK_out1, when the output of the output second lock signal LCK_out2 is terminated before an end section of the refresh frame FRr of the 60 Hz driving at which the output of the first and second data driving portions 221 and 222 is terminated, the synchronous lock signal LCKS can have a high level until the end section of the refresh frame FRr which is the earlier terminated point in time, and then be switched to a low level.

As such, in the case where the output second lock signal LCK_out2 is delayed compared to the output first lock signal LCK_out1 or terminated earlier than the output first lock signal LCK_out1 and thus the output first and second lock signals LCK_out1 and LCK_out2 are asynchronized with each other, the timing control portion 240 can turn off the transmission of the image data Do during the asynchronized section. In addition, in a section when the output second lock signal LCK_out2 has a high-level lock state and thus the synchronous lock signal LCKS has a high-level lock state, the timing control portion 240 can transmit the image data Do in response to the lock state of this synchronous lock signal LCKS.

As such, during the section when the output first and second lock signals LCK_outl and LCK_out2 are asynchronized, the transmission of the image data Do can be turned off to turn off the output of the first and second data voltages Vdata1 and Vdata2 at the top and bottom, and during the section when both the output first and second lock signals LCK_out1 and LCK_out2 are in a lock state, the transmission of the image data Do can be performed to synchronize and output the first and second data voltages Vdata1 and Vdata2 that are equal to each other.

Accordingly, a phenomenon can be alleviated or prevented in which in the asynchronized section of the output first and second lock signals LCK_out1 and LCK_out2, the output timings of the first data driving portion 221 at the top and the second data driving portion 222 at the bottom can be asynchronized, thus a potential difference in the output voltage occurs between the top and bottom channels, and thus an overcurrent occurs. Accordingly, it is possible to alleviate or prevent heating up or burning of the data ICs DIC due to the overcurrent occurring when the top and bottom outputs are asynchronized. In addition, it is possible to alleviate or prevent poor image quality, such as block dim, from occurring when the output asynchronized section is long.

In this regard, referring to the comparative example of FIG. 9, in a display apparatus of the comparative example, the power supply portion 280 provides a single input lock signal LCK_in to the first and second data driving portions 221 and 222, and the timing control portion 240 receives the output first and second lock signals LCK_out1 and LCK_out2 from the first and second data driving portions 221 and 222. When any one of the output first and second lock signals LCK_out1 and LCK_out2 is in a lock state, the image data Do is transmitted to the first and second data driving portions 221 and 222 regardless of whether they are synchronized or not, and the first and second data driving portions 221 and 222 outputs the corresponding data voltage Vdata1 and Vdata2.

In the driving of the comparative example, the image data Do is transmitted even in the asynchronized section between the output first and second lock signals LCK_out1 and LCK_out2, so that in the asynchronous section, for example, in the asynchronized section of the power-on sequence or the power-off sequence, the first data driving portion 221 outputs the first data voltage Vdata1 but the second data driving portion 222 cannot output the second data voltage Vdata2 which is the same as the first data voltage Vdata1. Accordingly, a potential difference in the output voltage occurs between the top and bottom channels, which may cause an overcurrent.

In contrast, in this embodiment, as mentioned above, the output first and second lock signals LCK_out1 and LCK_out2 are synchronized to generate the synchronous lock signal LCKS. Accordingly, during the asynchronized section between the output first and second lock signals LCK_out1 and LCK_out2, the output of the first and second data driving portions 221 and 222 can be turned off, and during the section where both are in a lock state, the output of the first and second data driving portions 221 and 222 can be performed. Accordingly, in the asynchronized section, the potential difference of the output voltage between the top and bottom channels can be alleviated or reduced, so that the overcurrent due to the potential difference can be improved.

In addition, in a case where at least one of the output first and second lock signals LCK_out1 and LCK_out2 is in a lock failure state, the timing control portion 240 can turn off the transmission of the image data Do during the lock failure section, and accordingly, the output of the data voltages Vdata1 and Vdata2 of the first and second data driving portions 221 and 222 can be turned off during this section.

For example, as shown in FIG. 8, in the refresh frame FRr of the 120 Hz driving, when the output second lock signal LCK_out2 is in a lock failure state (i.e., when the second data driving portion 222 has a lock failure), the synchronous lock signal LCKS can have a low level during the lock-failed refresh frame FRr.

As such, when the output second lock signal LCK_out2 is in a lock failure state, the timing control portion 240 can turn off the transmission of the image data Do during the lock failure section. In addition, in a section when the output second lock signal LCK_out2 is switched to a high-level lock state and the synchronous lock signal LCKS has a high-level lock state, the timing control portion 240 can transmit the image data Do in response to the lock state of the synchronous lock signal LCKS.

As such, during the section when the output second lock signal LCK_out2 is in an abnormal lock failure state, the transmission of the image data Do can be turned off to turn off the output of the first and second data voltages Vdata1 and Vdata2 at the top and bottom, and during the section where both are in a normal lock state, the transmission of the image data Do can be performed and thus the first and second data voltages Vdata1 and Vdata2 that are the same can be synchronized and output.

Accordingly, a phenomenon can be alleviated or prevented in which in the lock failure section, the first data driving portion 221 at the top performs a normal output and the second data driving portion 222 at the bottom performs an abnormal output, thus the potential difference of the output voltage between the top and bottom channels occurs, and thus an overcurrent occurs. Accordingly, the heating up or burning of the data IC DIC due to the overcurrent occurring when the lock fails can be alleviated or prevented.

In this regard, referring to the comparative example of FIG. 9, in the display apparatus of the comparative example, when one of the output first and second lock signals (LCK_out1, LCK_out2) is in a lock state, the image data Do is transmitted to the first and second data driving portions 221 and 222 regardless of whether the lock fails, and the first and second data driving portions 221 and 222 output the corresponding data voltages Vdata1 and Vdata2.

In the driving of the comparative example, the image data Do is transmitted even in the lock failure section, so that the first data driving portion 221 outputs the first data voltage Vdata1 normally, and the second data driving portion 222 does not output the second data voltage Vdata2 that is the same as the first data voltage Vdata1 normally but outputs the second data voltage Vdata2 abnormally. For example, the output voltage of the second data driving portion 222 has noise due to the lock failure.

Accordingly, a potential difference in the output voltage between the top and bottom channels occurs, which may cause an overcurrent. For example, the output voltage of the second data driving portion 222 is fixed to the source driving voltage SVDD, which may cause an overcurrent to occur toward the first data driving portion 221.

In contrast, in this embodiment, as mentioned above, the output first and second lock signals LCK_out1 and LCK_out2 are synchronized to generate the synchronous lock signal LCKS. Accordingly, during the lock failure section of the output second lock signal LCK_out2, the output of the first and second data driving portions 221 and 222 can be turned off. Accordingly, in the lock failure section, the potential difference in the output voltage between the top and bottom channels can be alleviated or reduced, so that the overcurrent due to the potential difference can be improved.

As described above, in the embodiment of the present disclosure, the input first and second lock signals can be input to the upper and lower data driving portions of the double bank structure, respectively, the output first and second lock signals output from the upper and lower data driving portions can be compared and synchronized in the comparison circuit to generate the synchronous lock signal, and the synchronous lock signal can be provided to the timing control portion, and the timing control portion can adjust the transmission timing of the image data according to the synchronous lock signal to synchronize the outputs of the data voltages from the upper and lower data driving portions.

Accordingly, the phenomenon in which the overcurrent occurs due to the potential difference in the output voltage between the upper and lower channels in the asynchronized section or the lock failure section can be improved.

Therefore, it is possible to improve the heating up or burning of the data IC of the upper and lower data driving portions due to the overcurrent. In addition, it is possible to improve the occurrence of poor image quality, such as block dim, when the asynchronized section is long.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display apparatus, comprising:
a display panel including a plurality of data lines and a plurality of pixels respectively connected to the plurality of data lines;
a first data driving portion including a plurality of first data integrated circuits (ICs) connected to one ends of the plurality of data lines;
a second data driving portion including a plurality of second data ICs connected to other ends of the plurality of data lines;
a timing control portion providing input first and second lock signals to the first data driving portion and the second data driving portion, respectively; and
a comparison circuit receiving output first and second lock signals generated from the first data driving portion and the second data driving portion according to the input first and second lock signals, respectively, and comparing and synchronizing the output first and second lock signals to provide a synchronous lock signal to the timing control portion,
wherein in a lock state of the synchronous lock signal, the timing control portion transmits image data to the first data driving portion and the second data driving portion, and the first data driving portion and the second data driving portion output respective data voltages.

2. The display apparatus of claim 1, wherein during a section when lock states of the output first and second lock signals are asynchronized with each other, the synchronous lock signal has an unlock state, and
wherein in the unlock state of the synchronous lock signal, the timing control portion turns off transmission of the image data, and outputs of the first data driving portion and the second data driving portion are turned off.

3. The display apparatus of claim 1, wherein during a section when at least one of the output first and second lock signals is in a lock failure state, the synchronous lock signal has an unlock state, and
wherein in the unlock state of the synchronous lock signal, the timing control portion turns off transmission of the image data, and outputs of the first data driving portion and the second data driving portion are turned off.

4. The display apparatus of claim 2, wherein in the section when the lock states of the output first and second lock signals are asynchronized with each other, one of the output first and second lock signals is in the lock state and another of the output first and second lock signals is in an unlock state.

5. The display apparatus of claim 3, wherein the at least one of the output first and second lock signals has an abnormal waveform in the lock failure state.

6. The display apparatus of claim 1, wherein when the input first lock signal is input, the plurality of first data ICs operate sequentially to output corresponding lock signals, and the lock signal output from one of the plurality of first data ICs is input to its next first data IC from the plurality of first data ICs, and the lock signal output from a last first data IC of the plurality of first data ICs is the output first lock signal, and
when the input second lock signal is input, the plurality of second data ICs operate sequentially to output corresponding lock signals, and the lock signal output from one of the plurality of second data ICs is input to its next second data IC from the plurality of second data ICs, and the lock signal output from a last second data IC of the plurality of second data ICs is the output second lock signal.

7. The display apparatus of claim 6, wherein the first data driving portion includes a first source board to which the plurality of first data ICs are connected,
wherein the second data driving portion includes a second source board to which the plurality of second data ICs are connected,
wherein the first source board includes a first lock signal line that transmits the lock signals inputted and outputted to the plurality of first data ICs, and
wherein the second source board includes a second lock signal line that transmits the lock signals inputted and outputted to the plurality of second data ICs.

8. The display apparatus of claim 1, wherein one of the plurality of pixels includes a light emitting diode.

9. The display apparatus of claim 1, wherein in the lock state of the synchronous lock signal, outputs of the data voltages of the first data driving portion and the second data driving portion are synchronized.

10. A display apparatus, comprising:
a display panel including a plurality of data lines and a plurality of pixels respectively connected to the plurality of data lines;
a first data driving portion including a plurality of first data integrated circuits (ICs) connected to one ends of the plurality of data lines;
a second data driving portion including a plurality of second data ICs connected to other ends of the plurality of data lines;
a timing control portion providing input first and second lock signals to the first data driving portion and the second data driving portion, respectively; and
a comparison circuit receiving output first and second lock signals generated from the first data driving portion and the second data driving portion according to the input first and second lock signals, respectively, and comparing and synchronizing the output first and second lock signals and providing a synchronous lock signal to the timing control portion,
wherein outputs of data voltages of the first data driving portion and the second data driving portion are adjusted according to the synchronous lock signal.

11. The display apparatus of claim 10, wherein in a lock state of the synchronous lock signal, the outputs of the data voltages of the first data driving portion and the second data driving portion are synchronized.

12. The display apparatus of claim 10, wherein during a section when lock states of the output first and second lock signals are asynchronized with each other, the synchronous lock signal has an unlock state, and
wherein in the unlock state of the synchronous lock signal, the outputs of the first data driving portion and the second data driving portion are turned off.

13. The display apparatus of claim 10, wherein during a section when at least one of the output first and second lock signals is in a lock failure state, the synchronous lock signal has an unlock state, and
wherein in the unlock state of the synchronous lock signal, the outputs of the first data driving portion and the second data driving portion are turned off.

14. The display apparatus of claim 12, wherein in the section when the lock states of the output first and second lock signals are asynchronized with each other, one of the output first and second lock signals is in the lock state and another of the output first and second lock signals is in an unlock state.

15. The display apparatus of claim 13, wherein the at least one of the output first and second lock signals has an abnormal waveform in the lock failure state.

16. The display apparatus of claim 10, wherein the first data driving portion includes a first source board to which the plurality of first data ICs are connected,
wherein the second data driving portion includes a second source board to which the plurality of second data ICs are connected,
wherein the first source board includes a first lock signal line that transmits the lock signals inputted and outputted to the plurality of first data ICs, and
wherein the second source board includes a second lock signal line that transmits the lock signals inputted and outputted to the plurality of second data ICs.

17. The display apparatus of claim 10, wherein one of the plurality of pixels includes a light emitting diode.

18. The display apparatus of claim 10, wherein the data voltages output from the first data driving portion and the second data driving portion are equal to each other.
